(19) United States
(12) Patent Application Publication
(10) Pub. No.: US 2007/0236889 A1
(43) Pub. Date: Oct. 11, 2007

(54) Electrical connector assembly with heat sink

(75) Inventor: Hao-Yun Ma, Tu-Cheng (TW)

Correspondence Address: WEI TE CHUNG;FOXCONN INTERNATIONAL, INC., 1650 MEMOREX DRIVE, SANTA CLARA, CA, 95050, US

(73) Assignee: HON HAI PRECISION IND. CO., LTD.

(21) Appl. No.: 11/784,839

(22) Filed: Apr. 10, 2007

(30) Foreign Application Priority Data
Apr. 10, 2006 (TW) 95205938

(51) Int. Cl. H05K 7/20

(52) U.S. Cl. 361/704; 361/715

(57) ABSTRACT

An electrical connector assembly includes an electrical connector (5) having a base (51) adapted to receive an IC package (7), the IC package on the base and having at least one electronic component (71) thereon, and a heat sink member (8) mountable upon the IC package with an exterior side (80) adapted to face said at least one electronic component. A recess (81) is defined on the exterior side and adapted for receiving the at least one electronic component. The inclusion of the recess on the heat sink member for receiving the electronic component has the advantage of preventing the deformation of the electronic component when force is increasingly imparted on the electronic component through pressure of the heat sink member.

### BACKGROUND OF THE INVENTION

1. Field of the Invention

The present invention relates to the art of electrical connectors, and more particularly to an electrical connector assembly including a heat sink member for dissipating heat from a circuit member, such as an IC package.

2. Description of the Related Art

As shown in FIG. 4, one conventional electrical connector assembly includes an electrical connector 5′ having a base adapted to receive an IC package 7′, the IC package on the base of the electrical connector and having at least one electronic component 71′, such as a die module, mounted thereon, and a heat sink member 8′ assembled onto the IC package 7′ for dissipating heat from the IC package 7′. FIG. 5 depicts a sketch view showing deformation of the IC package 7′ within the conventional electrical connector 5′ when imparting force on the IC package 7′ by pressure of the heat sink member 8′. A problem, however, with such an electrical connector assembly is that the die module 71′ is apt to be cracked or deformed if force is increasingly imparted on the die module 71′ through the pressure of the heat sink member 8′. This is so because the heat sink member 8′ is engageably mounted onto the die module 71′ of the IC package 7′, and the increasing pressure force is directly imparted onto the die module 71′, causing the die module 71′ to be cracked or deformed.

FIG. 6 shows another configuration of a conventional electrical connector assembly including an interposer 9′ sandwiched between the heat sink member 8′ and the IC package 7′. The interposer 9′ defines a recess 90′ for receiving the die module 71′ of the IC package 7′ in order to prevent the pressure force from the heat sink member 8′ to be directly exerted onto the die module 71′ to result in the crack or deformation of the die module 71′. However, the use of the interposer 9′ will in deed add the manufacturing cost of the electrical connector assembly, which is undesirable to the manufacturer in pursuit of lower and lower manufacturing costs. Therefore, there is a need to provide a new electrical connector assembly to resolve the above-mentioned shortcomings.

### SUMMARY OF THE INVENTION

One embodiment of the present invention provides an electrical connector assembly including an electrical connector, a heat sink member and an IC package. The electrical connector has a base adapted to receive the IC package. The IC package is adapted to be disposed on the base and has at least one electronic component mounted thereon. The heat sink member is adapted to be mounted upon the IC package, and has an exterior side adapted to face said at least one electronic component. A recess is defined on the exterior side of the heat sink member and adapted for receiving the at least one electronic component of the IC package. The inclusion of the recess on the heat sink member for receiving electronic component or components has the advantages of preventing the electronic component from being cracked or deformed when force is increasingly imparted on the electronic component of the IC package through the pressure of the heat sink member, as well as of reduced manufacturing cost due to having the interposer removed therefrom as compared with the prior art.

Other features and advantages of the present invention will become more apparent to those skilled in the art upon examination of the following drawings and detailed description of preferred embodiments, in which:

### BRIEF DESCRIPTION OF THE DRAWINGS

FIG. 1 is an exploded, perspective view of an electrical connector assembly including a heat sink member, an electrical connector and an IC package with at least one electronic component thereon;

FIG. 2 is a sketch, cross sectional view of an electrical connector assembly according to a first embodiment of the present invention, showing one electronic component of an IC package to be accommodated within a recess of a heat sink member;

FIG. 3 is a sketch, cross sectional view of an electrical connector assembly according to a second embodiment of the present invention, showing one electronic component of an IC package within a first recess of a heat sink member, and another electronic components within a second recess of the heat sink member;

FIG. 4 is a sketch view showing configuration of one conventional electrical connector assembly;

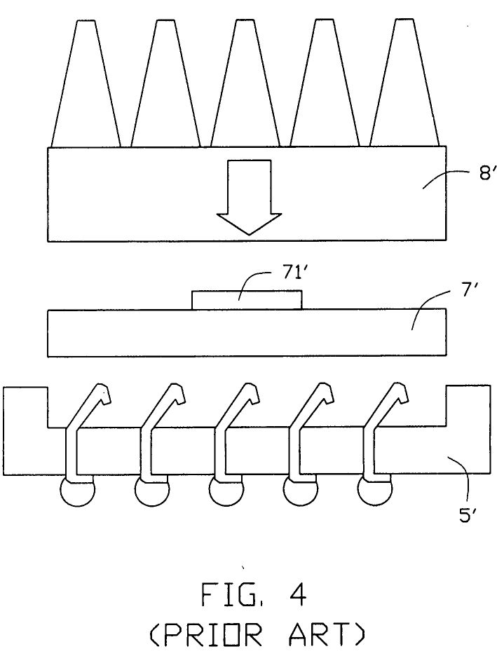

FIG. 5 is a sketch view showing deformation of the IC package of FIG. 4 when imparting force on the IC package by pressure of the heat sink member; and

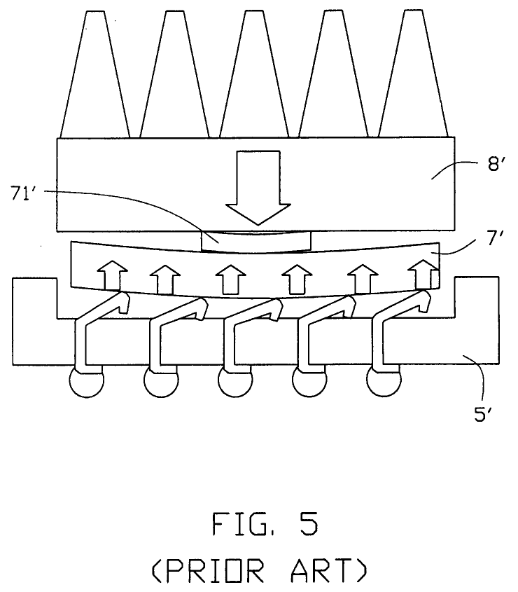

FIG. 6 is a sketch view showing configuration of another conventional electrical connector assembly.

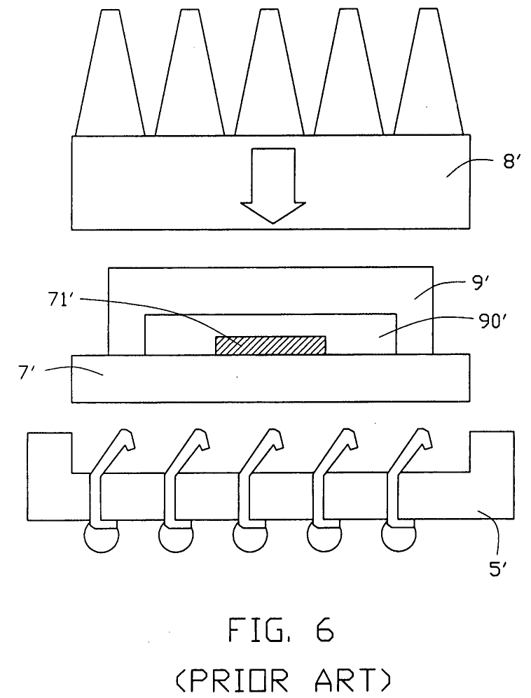

### DETAILED DESCRIPTION OF PREFERRED EMBODIMENT

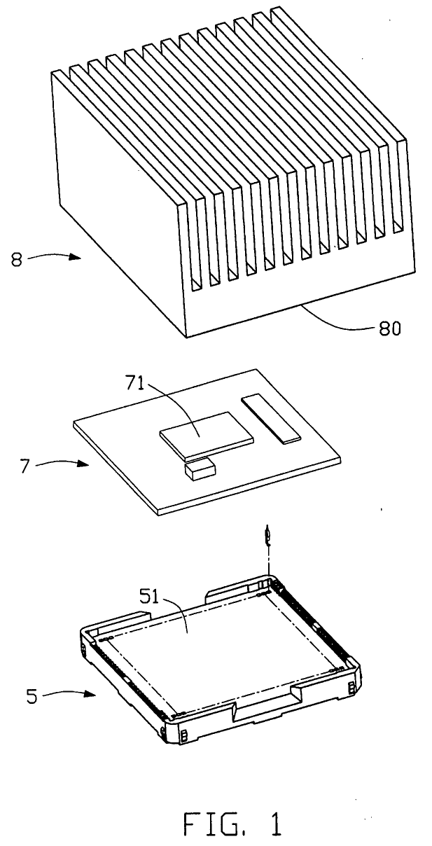

Referring to FIG. 1, an electrical connector assembly is shown to includes an electrical connector 5, an IC package 7 and a heat sink member 8. The electrical connector 5 includes a base 51 adapted to receive the IC package 7. The IC package 7 is adapted to be disposed on the base 51 of the electrical connector 5, and has at least one electronic component 71 mounted thereon. The heat sink member 8 is adapted to be mounted upon the IC package 7, the heat sink member 8 has an exterior side 80 adapted to be disposed in facing relationship to the at least one electronic component 71 of the IC package 7.

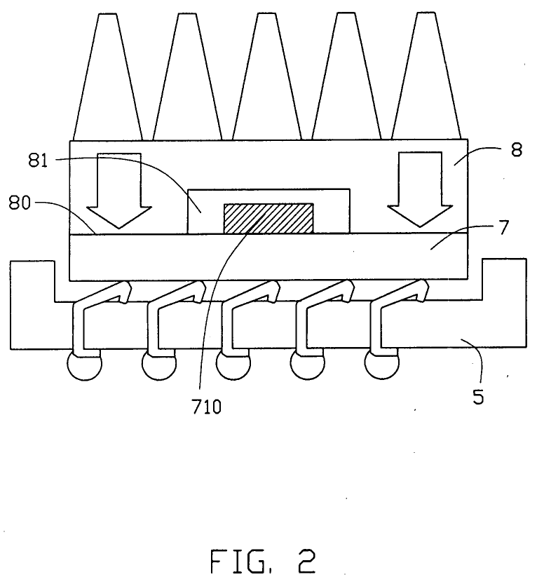

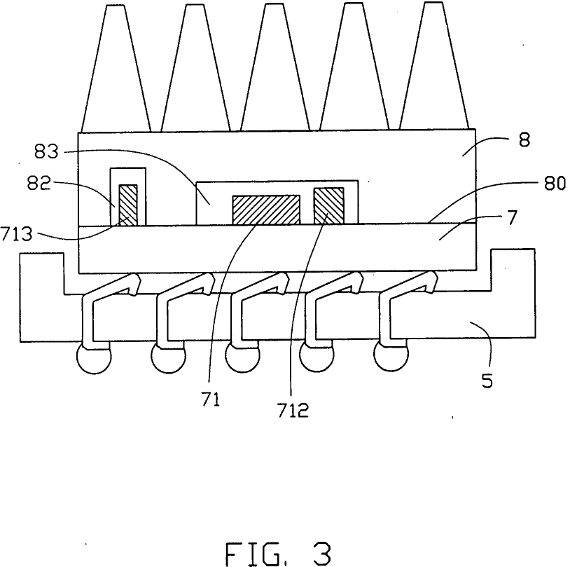

FIG. 2 depicts one configuration of the heat sink member of FIG. 1, showing one electronic component of the IC package to be accommodated within a recess of the heat sink member. More specifically, the heat sink member 8 defines a first recess 81 on the exterior side 80 of the heat sink member 8 and adapted for receiving the one electronic component 710 of the IC package 7. FIG. 3 depicts another configuration of the heat sink member of FIG. 1, showing one electronic component of the IC package within a first recess of the heat sink member, and another electronic components within a second recess of the heat sink member. More specifically, the heat sink member 8 defines the first recess 82 and the second recess 83 at different locations on the exterior side 80 of the heat sink member 8, with the first recess 82 adapted for receiving one electronic component 713 and the second recess 83 adapted for receiving another electronic components 711 and 712 of the IC package 7. The inclusion of the recess or recesses on the heat sink member 8 for receiving electronic component or components has the advantages of preventing the electronic component from being cracked or deformed when force is increasingly imparted on the electronic component of the IC package through pressure of the heat sink member 8, as well as of reduced manufacturing cost due to having the interposer removed therefrom as compared with the prior art.

While the present invention has been described with reference to preferred embodiments, the description of the invention is illustrative and is not to be construed as limiting the invention. Various of modifications to the present invention can be made to preferred embodiments by those skilled in the art without departing from the true spirit and scope of the invention as defined by the appended claims.

What is claimed is:

1. An electrical connector assembly comprising:
an electrical connector having a base adapted to receive an IC package;
the IC package on the base of the electrical connector and having a first electronic component thereon;
a heat sink member adapted to be mounted upon the IC package, the heat sink member having an exterior side adapted to face said at least one electronic component;
a first recess on said exterior side of the heat sink member and adapted for receiving said at least one electronic component of the IC package.

2. The electrical connector assembly of claim 1, wherein the IC package further includes a second electronic component mounted thereon, said first recess adapted for receiving the first and second electronic components.

3. The electrical connector assembly of claim 1, wherein the IC package further includes a second electronic component mounted thereon, the heat sink member has a second recess on said exterior side and adapted for receiving the second electronic component.

4. An electrical connector assembly comprising:
an electrical connector defining an insulative housing with a plurality of contacts upwardly extending above an upper surface thereof;
an IC package seated upon the connector and mechanically and electrically engaged with the contacts, said IC package including an electronic component upwardly extending above an upper face of the IC package;
a heat sink seated upon the upper face of the IC package while being distantly spaced from the electronic component in all directions.

5. The electrical connector assembly as claimed in claim 4, wherein the heat sink includes a base having thereon a bottom face engaged with the upper face of the IC package, and wherein a recess is formed in the bottom face to receive said electronic component therein without interference.

6. The electrical connector assembly as claimed in claim 4, wherein said heat sink surrounds said electronic component, and cooperates with the upper face of the IC package to veil said electronic component.
